(19) United States
(12) Patent Application Publication
(10) Pub. No.: US 2013/0180586 A1
(43) Pub. Date: Jul. 18, 2013

(54) SOLAR CELL

(71) Applicant: FUJIFILM Corporation, Tokyo (JP)

(72) Inventor: Yoshiki MAEHARA, Kanagawa (JP)

(73) Assignee: FUJIFILM CORPORATION, Tokyo (JP)

(21) Appl. No.: 13/786,027

(22) Filed: Mar. 5, 2013

Related U.S. Application Data
(63) Continuation of application No. PCT/JP2011/068972, filed on Aug. 23, 2011.

(30) Foreign Application Priority Data
Sep. 17, 2010 (JP) 2010-209973

(51) Int. Cl. H01L 31/0224

(52) U.S. Cl. CPC H01L 31/022425
USPC 136/256

(57) ABSTRACT

A solar cell 10 has a support 12, a positive electrode 20 disposed on the support, a photoelectric conversion layer 22 disposed on the positive electrode, a translucent metal negative electrode 26 which is disposed on the photoelectric conversion layer and is provided with a positive standard electrode potential, and an additional metal electrode 28 for the negative electrode, the additional metal electrode being disposed so as to be in contact with the metal negative electrode and being provided with a standard electrode potential that is less than the standard electrode potential of the metal negative electrode.

### CROSS-REFERENCE TO RELATED APPLICATION

This application is a continuation application of International Application No. PCT/JP2011/068972, filed on Aug. 23, 2011, which is incorporated herein by reference. Further, this application claims priority from Japanese Patent Application No. 2010-209973, filed on Sep. 17, 2010.

### TECHNICAL FIELD

The present invention relates to a solar cell.

### BACKGROUND ART

Recently, demand for solar cells has increased, and organic electronics devices that are expected to be able to reduce weight (enable flexibility) and lower costs are receiving attention. In particular, expectations regarding all-solid-state organic thin-film solar cells are rising.

Regarding the configuration of an organic thin-film solar cell, a bulk heterojunction type photoelectric conversion layer, which includes a mixture of an electron-donating material (donor) and an electron-accepting material (acceptor), being disposed between two dissimilar electrodes (a positive electrode and a negative electrode) is common practice, and therefore, organic thin-film solar cells are advantageous in that the production thereof is easier compared to conventional thin-film solar cells including amorphous silicon and the like, and in that solar cells of arbitrary area can be manufactured with low costs, and therefore, practical application thereof is desired.

In organic electronics devices such as organic thin-film solar cells, it is preferable that the electrode on the light receiving side has high transparency, from the viewpoint of power generation efficiency. As the transparent electrode, a transparent conductive oxide (TCO) is generally used, and particularly, indium tin oxide (ITO) is mainly used, since indium tin oxide can achieve both a high visible-light transparency and a high electric conductivity and can be manufactured easily. However, recently, the price of ITO materials is rising and, since high quality ITO electrodes can be obtained only by forming them in accordance with a physical vapor deposition (PVD) such as sputtering, there is a problem that the manufacturing cost is high. Therefore, under the present circumstances, an alternative for the electrode material is required.

Further, in a case of preparing a thin-film solar cell having optical transparency such as a translucent thin-film solar cell, it is necessary that both the positive electrode and the negative electrode have optical transparency. In a flexible thin-film solar cell having a support made of plastic film, or an organic thin-film solar cell having a photoelectric conversion layer formed from an organic semiconductor including a conductive polymer, or further, in a solar cell in which both are combined, the electrodes should be formed at a low temperature so as to prevent degradation of organic materials; however, when a film of TCO such as ITO is formed at a low temperature, the crystallinity thereof is insufficient, resulting in an increase in electrode resistance.

Here, U.S. Patent Application Publication No. 2009/0229667 discloses a transparent solar cell, in which a positive electrode including TCO or a conductive polymer is formed after forming, on a support, a mesh-patterned metal electrode as an additional electrode for the positive electrode, and further, an ultrathin film is formed as a translucent negative electrode by deposition of gold, silver, or the like.

Furthermore, as a method for reducing the resistance of a negative electrode formed from a light-transmitting metal ultrathin film, forming a mesh-patterned electrode, as an additional metal electrode, also on the negative electrode has been proposed (see, for example, Japanese Patent Application Laid-Open (JP-A) No. 2006-66707).

### DISCLOSURE OF INVENTION

### Technical Problem

In a case in which a negative electrode is formed using a silver ultrathin film which is sufficiently thin so as to transmit light, besides the increase of resistance simply due to the film thickness being thin, the resistance thereof is increased due to the change of quality caused by active factors derived from water, oxygen, or electrolytes, which contaminate during the production of or after the production of a solar cell, resulting in deterioration in photovoltaic characteristics.

Further, in a case of forming a mesh-patterned electrode as an additional metal electrode on a thin-film negative electrode, even though the resistance of the whole electrode is reduced, the region where light transmits is still an ultrathin film, and therefore, the problem of electrode degradation is not resolved.

An object of the present invention is to provide a solar cell with which deterioration in photovoltaic characteristics due to degradation of the negative electrode is suppressed.

### Solution to Problem

In order to accomplish the above object, the following invention is provided.
<1> A solar cell comprising:
   a support;
   a positive electrode disposed on the support;
   a photoelectric conversion layer disposed on the positive electrode;
   a translucent metal negative electrode which is disposed on the photoelectric conversion layer and is provided with a positive standard electrode potential; and
   an additional metal electrode for the negative electrode, the additional metal electrode being disposed so as to be in contact with the metal negative electrode and being provided with a standard electrode potential that is less than the standard electrode potential of the metal negative electrode.
<2> The solar cell according to <1>, wherein the metal negative electrode comprises at least one selected from the group consisting of copper, silver and gold, and the additional metal electrode for the negative electrode includes at least one selected from the group consisting of aluminum, nickel, copper and zinc.
<3> The solar cell according to <1> or <2>, wherein the photoelectric conversion layer includes an electron-donating region formed from an organic material.
<4> The solar cell according to <1> or <2>, wherein the photoelectric conversion layer has a bulk heterojunction.
<5> The solar cell according to any one of <1> to <4>, wherein an electron transport layer is disposed between the photoelectric conversion layer and the metal negative electrode.
<6> The solar cell according to <5>, wherein the electron transport layer comprises a metal that forms the additional metal electrode for the negative electrode.
<7> The solar cell according to any one of <1> to <6>, wherein the positive electrode comprises a first conductive layer disposed at a side of the support and a second conductive layer that is closer to the photoelectric conversion layer than the first conductive layer and has a higher volume resistivity than that of the first conductive layer.
<8> The solar cell according to any one of <1> to <7>, further comprising, an additional electrode for the positive electrode, the additional electrode being disposed so as to be in contact with the positive electrode.
<9> The solar cell according to <8>, wherein the additional electrode for the positive electrode comprises silver and a hydrophilic polymer.
<10> The solar cell according to any one of <1> to <9>, wherein the additional metal electrode for the negative electrode is disposed on the metal negative electrode.
<11> The solar cell according to any one of <1> to <9>, wherein at least a portion of the metal negative electrode is disposed on the additional metal electrode for the negative electrode.

### Advantage Effects of Invention

According to the present invention, a solar cell with which deterioration in photovoltaic characteristics due to degradation of the negative electrode is suppressed is provided.

### BRIEF DESCRIPTION OF DRAWINGS

FIG. 1 is a schematic cross-sectional view showing one example of the configuration of a solar cell of the present invention.

FIG. 2 is a schematic plane view showing one example of the arrangement of the additional metal electrode for the negative electrode of the solar cell shown in FIG. 1.

FIG. 3 is a schematic cross-sectional view showing another example of the configuration of a solar cell of the present invention.

### BEST MODE FOR CARRYING OUT THE INVENTION

Herein below, the contents of the invention are described in detail. Note that, in the present specification, the term “to” is used to indicate that the numerical values described in front of and behind “to” are included as the lower limit value and the upper limit value.

The solar cell according to the present invention has a support; a positive electrode disposed on the support; a photoelectric conversion layer disposed on the positive electrode; a translucent metal negative electrode which is disposed on the photoelectric conversion layer and is provided with a positive standard electrode potential; and an additional metal electrode for the negative electrode, the additional metal electrode being disposed so as to be in contact with the metal negative electrode and being provided with a standard electrode potential that is less than the standard electrode potential of the metal negative electrode. By having such a configuration, degradation of the additional metal electrode for the negative electrode proceeds further than the degradation of the metal negative electrode, and therefore, the degradation of the metal negative electrode can be suppressed.

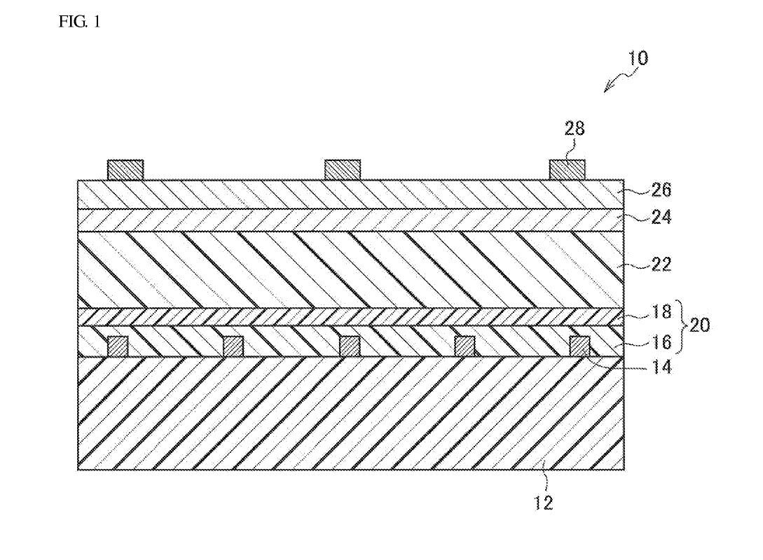

FIG. 1 schematically shows one example of the configuration of a solar cell according to the present invention. The solar cell according to the present exemplary embodiment has a support 12, an additional electrode 14 for the positive electrode, a positive electrode 20, a photoelectric conversion layer 22, an electron transport layer 24, a translucent metal negative electrode 26 provided with a positive standard electrode potential, and an additional metal electrode 28 for the negative electrode, the additional metal electrode being disposed so as to be in contact with the metal negative electrode 26 and being provided with a standard electrode potential that is less than the standard electrode potential of the metal negative electrode 26.

Herein below, materials which can be preferably used in the present invention and the like are described in detail.

<Support>

The support 12 which forms the solar cell of the present invention is not particularly limited as far as the support can hold thereon, by forming thereon, at least the positive electrode 20, the photoelectric conversion layer 22, the metal negative electrode 26, and the auxiliary electrode 28 for the negative electrode; and, for example, glass, plastic film, or the like can be selected as appropriate depending on the purpose. In the following, as a representative example of the support, a plastic film substrate is explained.

The plastic film substrate is not particularly limited with respect to the material, thickness, and the like, and can be selected as appropriate depending on the purpose; however, in the case of preparing an organic thin-film solar cell having optical transparency, it is preferable that the plastic film substrate has excellent transparency with respect to light, for example, light having the wavelength region of from 400 nm to 800 nm.

The optical transparency can be determined in accordance with the method described in JIS K7105, namely, by measuring the total light transparency and the amount of scattered light using an integrating sphere type optical transparency analyzer, and subtracting the diffuse transparency from the total light transparency, to calculate the optical transparency.

Specific examples of the material of the plastic film, which can be used for the support 12, include thermoplastic resins such as a polyester resin, a methacrylic resin, a methacrylic acid-maleic acid copolymer, a polystyrene resin, a transparent fluororesin, polyimide, a fluorinated polyimide resin, a polyamide resin, a polyamideimide resin, a polyetherimide resin, a cellulose acylate resin, a polyurethane resin, a polyether ether ketone resin, a polycarbonate resin, an alicyclic polyolefin resin, a polyarylate resin, a polyethersulfone resin, a polysulfone resin, a cycloolefin copolymer, a fluorene ring-modified polycarbonate resin, an alicycle-modified polycarbonate resin, a fluorene ring-modified polyester resin, and an acryloyl compound.

It is preferable that the plastic film substrate is formed from a material having heat resistance. Specifically, the plastic film substrate is preferably formed from a material having a heat resistance that satisfies at least any one of physical properties of a glass transition temperature (Tg) of 100° C. or higher and a linear thermal expansion coefficient of 40 ppm·K⁻¹ or less, and further having high transparency with respect to the exposure wavelength as described above.

Note that, the Tg and linear thermal expansion coefficient of plastic films may be measured by the transition temperature measuring method of plastics, which is described in JIS K7121, and by the test method for coefficient of linear thermal expansion of plastics according to thermomechanical analysis, which is described in JIS K7197; and in the present invention, values measured by these methods are used.

The Tg and linear thermal expansion coefficient of the plastic film substrate can be adjusted by using an additive or the like. Examples of such a thermoplastic resin having excellent heat resistance include polyethylene naphthalate (PEN: 120° C.), polycarbonate (PC: 140° C.), an alicyclic polyolefin (for example, ZEONOR 1600, manufactured by ZEON CORPORATION: 160° C.), polyarylate (PAr: 210° C.), polyethersulfone (PES: 220° C.), polysulfone (PSF: 190° C.), a cycloolefin copolymer (COC: a compound described in JP-A No. 2001-150584: 162° C.), fluorene ring-modified polycarbonate (BCF-PC: a compound described in JP-A No. 2000-227603: 225° C.), alicycle-modified polycarbonate (IP-PC: a compound described in JP-A No. 2000-227603: 205° C.), an acryloyl compound (a compound described in JP-A No. 2002-80616: 300° C. or higher), and polyimide (the numerical value in each of the parentheses indicates Tg); and these are preferable as the base material in the present invention. Among them, for use in which transparency is especially required, it is preferable to use an alicyclic polyolefin or the like.

It is required that the plastic film used as the support 12 is transparent with respect to light. More specifically, generally, the optical transparency with respect to light having the wavelength region of from 400 nm to 800 nm is preferably 80% or higher, more preferably 85% or higher, and even more preferably 90% or higher.

There is no particular limitation as to the thickness of the plastic film, but the thickness is typically from 1 μm to 800 μm, and preferably from 10 μm to 300 μm.

On the rear face of the plastic film (the face of a side on which the positive electrode is not provided), a known functional layer may be provided. Examples of the functional layer include a gas barrier layer, a matting agent layer, an antireflection layer, a hard coat layer, an antifogging layer, and an antifouling layer. In addition these, the functional layer is described in detail in paragraphs [0036] to [0038] of JP-A No. 2006-289627.

(Easily Adhesive Layer/Undercoat Layer)

The plastic film substrate 12 may have an easily adhesive layer or an undercoat layer on its front face (the face of a side on which the positive electrode is to be formed), from the viewpoint of improvement in adhesion. The easily adhesive layer or the undercoat layer may be a single layer or may be a multilayer.

Various hydrophilic undercoating polymers may be used for the formation of the easily adhesive layer or the undercoat layer. Examples of the hydrophilic undercoating polymers which may be used in the present invention include water-soluble polymers such as gelatin, a gelatin derivative, casein, agar, sodium alginate, starch, and polyvinyl alcohol; cellulose esters such as carboxymethyl cellulose and hydroxyethyl cellulose; latex polymers such as a vinyl chloride-containing copolymer, a vinylidene chloride-containing copolymer, an acrylic ester-containing copolymer, a vinyl acetate-containing copolymer, and a butadiene-containing copolymer; polyacrylic acid copolymers, and maleic anhydride copolymers.

The coating film thickness of the easily adhesive layer or undercoat layer after drying is preferably in a range of from 50 nm to 2 μm. In the case of using the support as a temporary support, it is possible to perform an easy-peelability-imparting treatment with respect to the surface of the support.

<Positive Electrode and Additional Electrode for Positive Electrode>

A positive electrode 20 is disposed on the support 12. The positive electrode 20 is selected from various conductive materials such as a metal, an alloy, TCO, or a conductive polymer. For example, in the case of preparing an organic thin-film solar cell having optical transparency, a conductive polymer layer can be formed as the positive electrode 20. Further, TCO such as ITO may be used for the positive electrode 20 or, in a case in which optical transparency is not needed, the positive electrode 20 may be formed by using a metal material such as nickel, molybdenum, silver, tungsten, or gold.

In the present exemplary embodiment, the positive electrode 20 is formed from two conductive polymer layers 16 and 18. The second conductive layer (high-resistance layer) 18 is disposed on the side of the photoelectric conversion layer 22, and has a higher volume resistivity than that of the first conductive layer (low-resistance layer) 16 which is disposed on the side of the support 12. When a high-resistance layer is disposed on the side of the photoelectric conversion layer 22 as described above, the transfer of electrons from the photoelectric conversion layer 22 to the positive electrode can be prevented. In a case in which the positive electrode 20 is made to have a laminate structure, the positive electrode may have three or more layers, but it is preferable that the positive electrode consists of two layers from the viewpoint of the manufacturing cost.

Further, an additional electrode 14 for the positive electrode, the additional electrode being in contact with the positive electrode 20, is disposed on the support 12. In the case of forming the positive electrode 20 by using a conductive polymer, when the additional electrode 14 for the positive electrode, the additional electrode having high conductivity, is provided so as to be in contact with the positive electrode 20, improvement in conductivity can be realized.

The additional electrode 14 for the positive electrode is formed to include a metal material of any kind. Examples of the metal material include gold, platinum, iron, copper, silver, aluminum, chrome, cobalt, and stainless steel. Preferable examples of the metal material include low-resistance metals such as copper, silver, aluminum, and gold; and among them, silver or copper is preferably used, since the manufacturing cost and the material cost are low, and they are less likely to oxidize.

The pattern shape of the additional electrode 14 for the positive electrode is not particularly limited, but a mesh-shaped one (mesh-patterned electrode) is preferable from the viewpoints of optical transparency and conductivity. There is no particular limitation on the mesh pattern, and a grid shape of square, rectangle, diamond shape, or the like, a banded shape (a striped shape), honeycomb, or a combination of curves may be used.

The mesh design thereof is adjusted so that the aperture ratio (optical transparency) and the surface resistance (electric conductivity) become the desired values. In the case of preparing such a mesh-patterned additional electrode 14 for the positive electrode, the aperture ratio of the mesh is generally 70% or higher, preferably 80% or higher, and more preferably 85% or higher.

The surface resistance of the additional electrode 14 for the positive electrode in the state of being not provided with the conductive polymer layers 16 and 18 is preferably 10 Ω/□ or less, more preferably 3 Ω/□ or less, and even more preferably 1 Ω/□ or less. Since the optical transparency and the electric conductivity are in a trade-off relationship, it is preferable to have a greater aperture ratio, but actually, the aperture ratio is 95% or less.

The thickness of the additional electrode 14 for the positive electrode is not particularly limited, but the thickness is generally from about 0.02 μm to about 20 μm.

From the viewpoints of optical transparency and conductivity, the line width of the additional electrode 14 for the positive electrode is, by the line width in planar view, in a range of from 1 μm to 500 μm, preferably from 1 μm to 100 μm, and more preferably from 3 μm to 20 μm.

The conductive polymer layer 16 which is formed so as to be in contact with the additional electrode 14 for the positive electrode has a lower hole mobility and a lower electron mobility as compared to the additional electrode 14 for the positive electrode made of a metal. Therefore, it is advantageous that the pitch of the additional electrode 14 for the positive electrode is smaller (the mesh is finer) in terms of solar cell characteristics. However, when the pitch is small, the transparency of light is decreased, accordingly, a point of compromise is selected. The pitch changes according to the line width of the additional thin metallic electrode, but the pitch in planar view is preferably from 50 μm to 2000 μm, more preferably from 100 μm to 1000 μm, and even more preferably from 150 μm to 500 μm.

With regard to the opening, the area of the opening which is the repeating unit of the additional electrode 14 for the positive electrode is preferably from 1×10⁻⁹ m² to 1×10⁻⁵ m², more preferably from 3×10⁻⁹ m² to 1×10⁻⁶ m², and even more preferably from 1×10⁻⁸ m² to 1×10⁻⁷ m².

The additional electrode 14 for the positive electrode may have a bus line (thick line) for the purpose of large-area power collection. The line width and pitch of the bus line may be selected as appropriate depending on the material used.

The method of forming the additional electrode 14 for the positive electrode is not particularly limited, and a known formation method can be appropriately used. Examples of the method include a method of pasting a mesh-patterned metal, which is prepared in advance, onto a surface of a support; a method of coating a conductive material in a mesh pattern; a method of forming a conductive film on the whole surface using a PVD method such as deposition or sputtering, and then performing etching to form a mesh-patterned conductive film; a method of coating a mesh-patterned conductive material by various printing methods such as screen printing and inkjet printing; a method of directly forming a mesh-patterned additional electrode for a positive electrode on a surface of a base material by performing deposition or sputtering using a shadow mask; and a method of using a silver halide photosensitive material (herein below, may be referred to as a “silver salt method”) as described in JP-A Nos. 2006-352073 and 2009-231194, and the like.

In the case of forming the additional electrode 14 for the positive electrode as a mesh electrode, since the pitch thereof is small, it is preferable to form the additional electrode by the silver salt method. In the case of forming the additional electrode 14 for the positive electrode by the silver salt method, a coating liquid for forming the additional electrode 14 for the positive electrode is provided on the support, and by a process of performing pattern exposure with respect to the coated film for forming the additional electrode 14 for the positive electrode, a process of developing the pattern-exposed coated film, and a process of fixing the developed coated film, the additional electrode 14 for the positive electrode, the additional electrode having a desired pattern, can be formed on the support.

The additional electrode 14 for the positive electrode, which is prepared by the silver salt method, is a layer including silver and a hydrophilic polymer. Examples of the hydrophilic polymer include water-soluble polymers such as gelatin, a gelatin derivative, casein, agar, sodium alginate, starch, and polyvinyl alcohol; and cellulose esters such as carboxymethyl cellulose and hydroxyethyl cellulose. In the layer, other than the silver and the hydrophilic polymer, substances derived from the coating, developing, and fixing processes are included.

A method of performing copper plating, after forming the additional electrode for the positive electrode by the silver salt method, to obtain an additional electrode for the positive electrode, the additional electrode having a further lower resistance, is also preferably used.

In the case of preparing a transparent solar cell, each of the conductive polymer layers 16 and 18, which form the positive electrode 20, should be transparent in the action spectrum range for the solar cell to be applied; and generally, each of the conductive polymer layers should have excellent transparency with respect to light of from the visible light to the near infrared light. Specifically, when each of the conductive polymer layers is formed to have a thickness of 0.2 μm, the average optical transparency in the wavelength region of from 400 nm to 800 nm is preferably 75% or higher, and more preferably 85% or higher.

The material that forms each of the conductive polymer layers 16 and 18 is not particularly limited as far as the material is a polymer material having conductivity. Regarding the charge carrier for transport, any of holes or electrons may be employed. Specific examples of the conductive polymer include polythiophene, polypyrrole, polyaniline, polyphenylene vinylene, polyphenylene, polyacetylene, polyquinoxaline, polyoxadiazole, polybenzothiadiazole, and polymers including plurality of these conductive frameworks.

Among them, polythiophene is preferable, and polyethylene dioxythiophene and polythienothiophene are particularly preferable. Generally, these polythiophenes are partially oxidized in order to obtain conductivity. The electric conductivity of the conductive polymer can be adjusted by the degree of partial oxidation (the doped amount), and as the doped amount gets larger, the electric conductivity becomes higher. Since polythiophene becomes cationic by partial oxidation, counter anions are needed to neutralize the charges. Examples of such polythiophene include polyethylene dioxythiophene with polystyrene sulfonic acid as the counter ion (PEDOT-PSS).

Each of the conductive polymer layers 16 and 18 may further have an additional polymer added therein to the extent of not impairing the desired conductivity. The additional polymer may be added for the purpose of improving the coating property or for the purpose of enhancing the film strength. Examples of the additional polymer include thermoplastic resins such as a polyester resin, a methacrylic resin, a methacrylic acid-maleic acid copolymer, a polystyrene resin, a transparent fluororesin, polyimide, a fluorinated polyimide resin, a polyamide resin, a polyamideimide resin, a polyetherimide resin, a cellulose acylate resin, a polyurethane resin, a polyether ether ketone resin, a polycarbonate resin, an alicyclic polyolefin resin, a polyarylate resin, a polyethersulfone resin, a polysulfone resin, a cycloolefin copolymer, a fluorene ring-modified polycarbonate resin, an alicycle-modified polycarbonate resin, a fluorene ring-modified polyester resin, and an acryloyl compound, and hydrophilic polymers such as gelatin, polyvinyl alcohol, polyacrylic acid, polyacrylamide, polyvinyl pyrrolidone, polyvinyl pyridine, and polyvinyl imidazole. These polymers may be crosslinked in order to enhance the film strength.

It is preferable that the first conductive layer 16 includes a conductive polymer having a volume resistivity of 1×10⁻¹ Ω·cm or less by itself, and it is more preferable that the first conductive layer 16 includes a conductive polymer having a volume resistivity of 1×10⁻² Ω·cm or less. It is preferable that the volume resistivity of the first conductive layer 16 becomes 5×10⁻¹ Ω·cm or less, and more preferably 5×10⁻² Ω·cm or less, by the inclusion of such a conductive polymer (preferably, a polythiophene derivative). When a low-resistance first conductive layer 16 having a volume resistivity as described above is formed so as to be in contact with the opening of the additional electrode 14 of the positive electrode and the additional electrode 14 of the positive electrode, conductivity is imparted also to the opening of the additional electrode 14 of the positive electrode and, as a result, the conversion efficiency of the solar cell can be improved.

Note that, the low-resistance first conductive layer 16 is not necessarily formed on the additional electrode 14 of the positive electrode, and it is enough that the first conductive layer 16 is formed so as to be in contact with the additional electrode 14 of the positive electrode at least at the inner part of the opening of the additional electrode 14 of the positive electrode. For example, the first conductive layer (low-resistance layer) 16 may be provided at the inner part of the opening of the additional electrode 14 of the positive electrode, and the second conductive layer (high-resistance layer) 18 may be formed on the additional electrode 14 of the positive electrode and on the first conductive layer 16.

It is preferable that the second conductive layer 18 includes a conductive polymer having a volume resistivity of 10 Ω·cm or more, and it is more preferable that the second conductive layer 18 includes a conductive polymer having a volume resistivity of 100 Ω·cm or more. It is preferable that the volume resistivity of the second conductive layer 18 becomes 10 Ω·cm or more, and more preferably 100 Ω·cm or more, by the inclusion of such a conductive polymer (preferably, a polythiophene derivative). When a high-resistance second conductive layer 18 having a volume resistivity as described above is formed on the first conductive layer 16, the transfer of electrons from the photoelectric conversion layer to the positive electrode is prevented and, as a result, improvement in conversion efficiency of the solar cell can be realized. From the role as described above, the second conductive layer 18 can be considered as an electron blocking layer or a hole transport layer.

Since conductive polymers are in the form of an aqueous solution or a water dispersion in many cases, a generally used water-based coating method is used for the formation of each of the conductive polymer layers 16 and 18. In a case in which the additional electrode for the positive electrode is prepared by the silver salt method, the hydrophilic polymer exists around the additional electrode for the positive electrode, and therefore, it is convenient to apply a water dispersion. Various kinds of solvents, surfactants, thickeners, or the like may be added to the conductive polymer coating liquid for use as a coating aid.

The film thickness of the first conductive polymer layer 16 is preferably in a range of from 30 nm to 3 μm, and more preferably from 100 nm to 1 μm, from the viewpoints of conductivity and transparency.

The film thickness of the second conductive polymer layer 18 is preferably in a range of from 1 nm to 100 nm, and more preferably from 5 nm to 50 nm, from the viewpoints of blocking electrons and transporting holes.

<Functional Layer>

A functional layer may be provided on the rear side (the side on which the positive electrode is not formed) of the support 12. Examples of the functional layer include a gas barrier layer, a matting agent layer, an antireflection layer, a hard coat layer, an antifogging layer, an antifouling layer, and an easily adhesive layer. In addition, the functional layer is described in detail in paragraphs [0036] to [0038] of JP-A No. 2006-289627, and the functional layer described in this document may be provided depending on the purpose.

<Photoelectric Conversion Layer>

A photoelectric conversion layer 22 is provided on the positive electrode 20. The photoelectric conversion layer 22 is configured by selecting a material from materials that exhibit high efficiency in the photoelectric conversion process, in which, after excitons (electron-hole pairs) are generated by receiving the sunlight, the excitons split into electrons and holes, and the electrons are transported toward the negative electrode side and the holes are transported toward the positive electrode side. In the case of preparing an organic thin-film solar cell, a photoelectric conversion layer 22 including an electron-donating region (donor) formed from an organic material is formed and, from the viewpoint of conversion efficiency, a bulk heterojunction type photoelectric conversion layer (as appropriate, referred to as a “bulk hetero layer”) is preferably applied.

The bulk hetero layer is an organic photoelectric conversion layer including a mixture of an electron-donating material (donor) and an electron-accepting material (acceptor). The mixing ratio of the electron-donating material to the electron-accepting material is adjusted so as to exhibit the highest conversion efficiency, but generally, the mixing ratio is selected from the range of from 10:90 to 90:10 by mass ratio. As the method of forming such a mixed layer, for example, a codeposition method is used. Alternatively, it is possible to prepare such a mixed layer by solvent coating using a solvent that is common to both the organic materials. Specific examples of the solvent coating method are described below.

The film thickness of the bulk hetero layer is preferably from 10 nm to 500 nm, and particularly preferably from 20 nm to 300 nm.

The electron-donating material (which may also be referred to as “donor” or “hole transporting material”) is a π-electron conjugated compound in which the highest occupied molecular orbital (HOMO) level thereof is from 4.5 eV to 6.0 eV, and specifically, examples include conjugated polymers which are obtained by coupling of various arenes (for example, thiophene, carbazole, fluorene, silafluorene, thienopyrazine, thienobenzothiophene, dithienosilole, quinoxaline, benzothiadiazole, thienothiophene, or the like), phenylene vinylene-based polymers, porphyrins, and phthalocyanines. Further, compound groups described as “Hole-Transporting Materials” in Chemical Review, vol. 107, pages 953 to 1010 (2007), and porphyrin derivatives described in Journal of the American Chemical Society, vol. 131, page 16048 (2009) can also be applied.

Among them, a conjugated polymer which is obtained by coupling a structural unit selected from the group consisting of thiophene, carbazole, fluorene, silafluorene, thienopyrazine, thienobenzothiophene, dithienosilole, quinoxaline, benzothiadiazole, and thienothiophene is particularly preferable. Specific examples thereof include poly-3-hexylthiophene (P3HT), poly-3-octylthiophene (P3OT), various polythiophene derivatives described in Journal of the American Chemical Society, vol. 130, page 3020 (2008), PCDTBT described in Advanced Materials, vol. 19, page 2295 (2007), PCDTQx, PCDTPP, PCDTPT, PCDTBX, and PCDTPX described in Journal of the American Chemical Society, vol. 130, page 732 (2008), PBDTTT-E, PBDTTT-C, and PBDTTT-CF described in Nature Photonics, vol. 3, page 649 (2009), and PTB7 described in Advanced Materials, vol. 22, pages E135 to E138 (2010).

The electron-accepting material (which may also be referred to as “acceptor” or “electron transporting material”) is a π-electron conjugated compound in which the lowest unoccupied molecular orbital (LUMO) level thereof is from 3.5 eV to 4.5 eV, and specifically, examples include fullerene and derivatives thereof, phenylene vinylene-based polymers, naphthalene tetracarboxylic imide derivatives, and perylene tetracarboxylic imide derivatives. Among them, fullerene derivatives are preferable. Specific examples of the fullerene derivatives include C₆₀, phenyl-C₆₁-butyric acid methyl ester (fullerene derivatives referred to as PCBM, [60]PCBM, or PC₆₁BM in literatures and the like), C₇₀, phenyl-C₇₁-butyric acid methyl ester (fullerene derivatives referred to as PCBM, [70]PCBM, or PC₇₁BM in many literatures and the like), fullerene derivatives described in Advanced Functional Materials, vol. 19, pages 779 to 788 (2009), and fullerene derivative SIMEF described in Journal of the American Chemical Society, vol. 131, page 16048 (2009).

<Recombination Layer>

The solar cell according to the present invention may have a configuration of a so-called tandem type, in which plural photoelectric conversion layers are laminated. The tandem type configuration may be a series connection type or may be a parallel connection type.

In a tandem type element having two photoelectric conversion layers, a recombination layer is provided between the two photoelectric conversion layers. An ultrathin film of a conductive material is used as the material for the recombination layer. Preferable examples of the conductive material include gold, silver, aluminum, platinum, titanium oxide, and ruthenium oxide. Among them, silver is preferable since silver is relatively cheap and stable. The film thickness of the recombination layer is from 0.01 nm to 5 nm, preferably from 0.1 nm to 1 nm, and particularly preferably from 0.2 nm to 0.6 nm. The method of forming the recombination layer is not particularly limited, and the recombination layer can be formed by, for example, a PVD method such as a vacuum deposition method, a sputtering method, or an ion plating method.

<Electron Transport Layer>

As necessary, an electron transfer layer 24 formed from an electron transporting material may be provided between the bulk hetero layer 22 and the metal negative electrode 26. Examples of the electron transporting material, which can be used in the electron transfer layer 24, include the electron-accepting materials described in the above description of the photoelectric conversion layer and those described as “Electron-Transporting and Hole-Blocking Materials” in Chemical Review, vol. 107, pages 953 to 1010 (2007). Various metal oxides are also preferably used as the material having high stability for the electron transport layer, and examples thereof include lithium oxide, magnesium oxide, aluminum oxide, calcium oxide, titanium oxide, zinc oxide, strontium oxide, niobium oxide, ruthenium oxide, indium oxide, zinc oxide, and barium oxide. Among them, aluminum oxide, titanium oxide, and zinc oxide, which are relatively stable, are more preferable. The film thickness of the electron transfer layer is from 0.1 nm to 500 nm, and preferably from 0.5 nm to 300 nm. The electron transfer layer 24 can be preferably formed according to any of a wet film-forming method such as coating or the like, a dry film-forming method such as a PVD method, for example, deposition or sputtering, a transfer method, a printing method, and the like.

<Additional Semiconductor Layer>

As necessary, the solar cell of the invention may have one or more auxiliary layers such as a hole blocking layer or an exciton-diffusion-preventing layer. Note that, in the present invention, the term “semiconductor layer” is used as a general term for layers that transport electrons or holes, such as a bulk hetero layer, a hole transport layer, a hole injection layer, an electron transport layer, an electron injection layer, an electron blocking layer, a hole blocking layer, and an exciton diffusion preventing layer, which are formed between the positive electrode 20 and the metal negative electrode 26.

<Metal Negative Electrode>

The negative electrode of the solar cell according to the present invention is a translucent metal negative electrode 26 which is provided with a positive standard electrode potential. The standard electrode potential of a metal material in the invention means the electrode potential of the working electrode in the normal state in an electrochemical system (chemical cell), in which the standard hydrogen electrode is designated as the standard electrode (reference electrode) and the intended metal material is designated as the working electrode (work electrode), and is equivalent to the electromotive force of the chemical cell. Detailed explanation of the standard electrode potential and standard electrode potential values of metal materials can be referred to in the description of “DENKI KAGAKU BINRAN (Handbook of Electrochemistry) fifth edition”, edited by Denki Kagaku Kyokai (The Electrochemical Society of Japan), pages 91 to 98, Maruzen (2000) and the like.

Examples of the material, which forms the metal negative electrode 26, include copper, palladium, silver, platinum, and gold; and particularly, from the viewpoint of electric conductivity, it is preferable that at least one selected from the group consisting of copper (standard electrode potential: 0.3 V), silver (standard electrode potential: 0.8 V), and gold (standard electrode potential: 1.5 V) is included.

The method of forming the metal negative electrode 26 is not particularly limited, and the formation of the metal negative electrode can be conducted according to a known method. For example, the metal negative electrode can be formed in accordance with a method which is selected as appropriate from among wet film-forming methods such as coating and printing; dry film-forming methods such as PVD methods, for example, a vacuum deposition method, a sputtering method, and an ion plating method and chemical vapor deposition methods (CVD methods); and the like, considering the suitability to the above-described material that forms the metal negative electrode 26.

Patterning in the formation of the metal negative electrode 26 may be conducted in accordance with chemical etching by photolithography or the like; may be conducted in accordance with physical etching by laser or the like; may be conducted by superposing a shadow mask and carrying out vacuum deposition, sputtering, or the like; or may be conducted in accordance with a lift-off method or a printing method.

The position of the metal negative electrode 26 to be formed is not particularly limited as far as the metal negative electrode is disposed opposed to the positive electrode 20 so as to sandwich the semiconductor layer such as the photoelectric conversion layer 22, and the metal negative electrode may be formed on the whole surface of the semiconductor layer, or may be formed on a portion of the semiconductor layer. Further, between the metal negative electrode 26 and the semiconductor layer, a dielectric layer which includes a fluoride or oxide of an alkaline metal or alkaline earth metal, and has a thickness of from 0.1 nm to 5 nm may be inserted. This dielectric layer may be deemed as a kind of electron injection layer. The dielectric layer can be formed by, for example, a PVD method such as a vacuum deposition method, a sputtering method, or an ion plating method.

The thickness of the metal negative electrode 26 can be selected as appropriate depending on the material that forms the metal negative electrode 26 and cannot be defined unconditionally but, from the viewpoints of optical transparency and conductivity, the thickness is generally from about 5 nm to about 50 nm, and preferably from 10 nm to 30 nm.

<Additional Metal Electrode for Negative Electrode>

In the solar cell 10 according to the present invention, an additional metal electrode 28 for the negative electrode, the additional metal electrode having a standard electrode potential that is less than the standard electrode potential of the metal negative electrode 26, is disposed so as to be in contact with the metal negative electrode 26.

In the case of using the metal negative electrode 26, as the thickness thereof gets thinner, a higher optical transparency can be obtained, however, the resistance becomes higher, and besides, degradation occurs due to oxidization or the like, resulting in lowering the durability of the solar cell. However, when the additional metal electrode 28 for the negative electrode, the additional metal electrode having a standard electrode potential that is less than the standard electrode potential of the metal negative electrode 26 is disposed so as to be in contact with the metal negative electrode 26, degradation of the additional metal electrode 28 for the negative electrode occurs prior to the degradation of the metal negative electrode 26, and therefore, the deterioration (change of quality) of the metal negative electrode 26 can be suppressed.

Examples of the material which forms the additional metal electrode 28 for the negative electrode include aluminum, iron, cobalt, nickel, copper, zinc, molybdenum, cadmium, indium, tin, and tungsten; and particularly, from the viewpoint of the stability in the air and the electric conductivity, it is preferable that at least one selected from the group consisting of aluminum (standard electrode potential: −1.7 V), nickel (standard electrode potential: −0.2 V), copper (standard electrode potential: 0.3 V), and zinc (standard electrode potential: −0.8 V) is included.

The method of forming the additional metal electrode 28 for the negative electrode is not particularly limited, and can be conducted according to a known method. For example, the additional metal electrode can be formed in accordance with a method which is selected as appropriate from among wet film-forming methods such as coating and printing; dry film-forming methods such as PVD methods, for example, a vacuum deposition method, a sputtering method, and an ion plating method and various CVD methods, considering the suitability to the above-described material that forms the additional metal electrode 28 for the negative electrode.

Patterning in the formation of the additional metal electrode 28 for the negative electrode may be conducted in accordance with chemical etching by photolithography or the like; may be conducted in accordance with physical etching by laser or the like; may be conducted by superposing a shadow mask and carrying out vacuum deposition, sputtering, or the like; or may be conducted in accordance with a lift-off method or a printing method.

Regarding the position of the additional metal electrode 28 for the negative electrode to be formed, it is enough that the additional metal electrode is in contact with at least the metal negative electrode 26, and may be formed on the upper side or the lower side of the metal negative electrode 26, but from the viewpoint of exposing the additional metal electrode 28 for the negative electrode in order to preferentially degrade the additional metal electrode, it is preferable to form the additional metal electrode on the metal negative electrode.

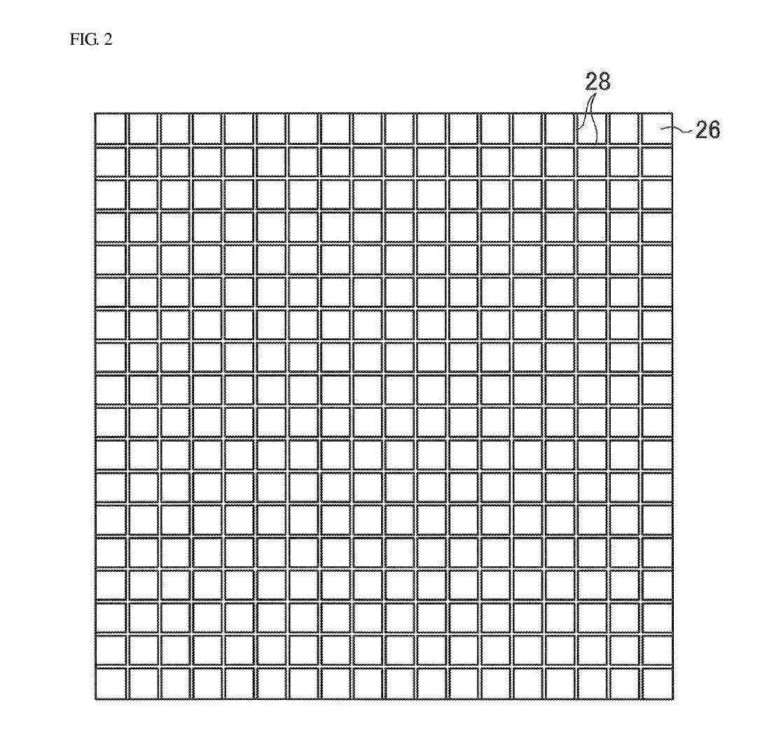

For example, when a grid-like additional metal electrode 28 for the negative electrode is formed on the metal negative electrode 26 as shown in FIG. 2, the degradation of the metal negative electrode 26 is suppressed, and also, the optical transparency and the electric conductivity can be ensured.

The line width of the additional metal electrode 28 for the negative electrode in planer view is preferably from 0.001 mm to 1 mm, and more preferably from 0.005 mm to 0.5 mm.

Further, the pitch of the additional metal electrode 28 for the negative electrode in planar view is preferably 0.05 mm or more, and more preferably 0.1 mm or more.

The thickness of the additional metal electrode 28 for the negative electrode can be selected as appropriate depending on the material of the metal negative electrode 26 and the material of the additional metal electrode 28 for the negative electrode, and cannot be defined unconditionally but, from the viewpoints of effectively suppressing the degradation of the metal negative electrode 26 and ensuring the optical transparency and the electric conductivity, the thickness is preferably from 0.05 μm to 20 μm, and more preferably from 0.1 μm to 10 μm.

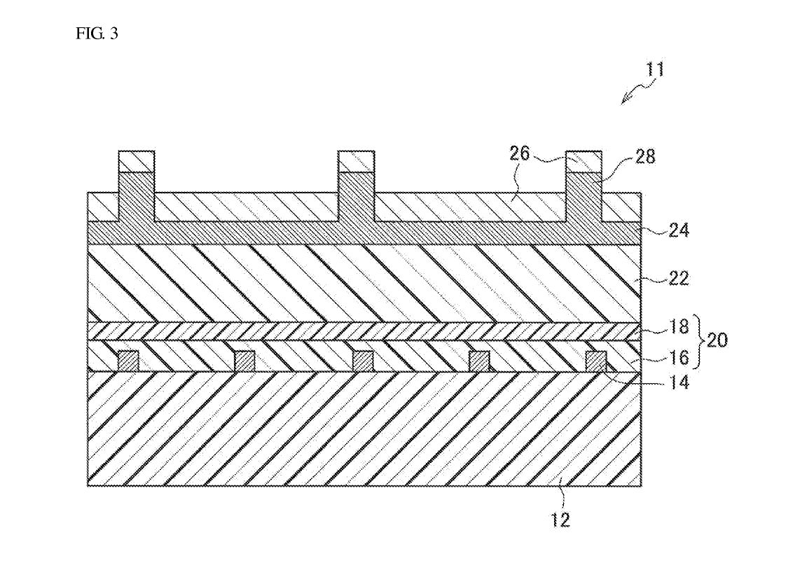

FIG. 3 schematically shows another example of the configuration of a solar cell according to the present invention.

This solar cell 11 is configured so that the electron transport layer 24 includes the metal that forms the additional metal electrode 28 for the negative electrode. For example, after forming the electron transport layer 24 and before forming the metal negative electrode 26, the additional metal electrode 28 for the negative electrode can be formed using a shadow mask. That is, by successively forming the electron transport layer 24 and the additional metal electrode 28 for the negative electrode using the same metal material, the manufacturing cost can be reduced. When the thickness of the electron transport layer 24 is made thinner (for example, film thickness of 10 nm or less), the electron transport layer 24 can be made transparent by performing, subsequently, a heat treatment (annealing) to oxidize. In the case of successively forming the electron transport layer 24 and the additional metal electrode 28 for the negative electrode in such a manner, the metal that forms the electron transport layer 24 and the additional metal electrode 28 for the negative electrode is preferably aluminum or zinc.

After forming the electron transport layer 24 and the additional metal electrode 28 for the negative electrode, the metal negative electrode 26 may be formed by a PVD method such as deposition and sputtering. In this case, when the metal negative electrode is formed such that the film thickness of the metal negative electrode 26 is thinner than the film thickness of the additional metal electrode 28 for the negative electrode, and thus, a portion of the additional metal electrode 28 for the negative electrode exposes from the metal negative electrode, the metal negative electrode 26 is to be formed on the electron transport layer 24 and besides, a portion of the metal negative electrode is to be formed on the additional metal electrode 28 for the negative electrode; whereby, the degradation of the metal negative electrode 26 is suppressed and also the optical transparency and the electric conductivity can be ensured.

<Heat Treatment>

The organic thin-film solar cell according to the present invention may be subjected to a heat treatment (annealing) by various methods, for the purpose of accelerating the phase separation of the electron-donating region (donor) and the electron-accepting region (acceptor) in the photoelectric conversion layer, crystallizing the organic material included in the photoelectric conversion layer, forming a transparent electron transport layer, or the like. For example, in the case of a dry film-forming method such as deposition, there is a method of heating the substrate to a temperature of from 50° C. to 150° C. during film formation. In the case of a wet film-forming method such as printing or coating, there is a method of setting the drying temperature after coating to 50° C. to 150° C. or the like. Further, heating to a temperature of from 50° C. to 150° C. may be conducted after the formation of the metal negative electrode has been completed.

<Passivation Layer>

The solar cell 10 according to the present invention may be covered with a passivation layer. Examples of a material which may be included in the passivation layer include inorganic materials such as metal oxides, for example, magnesium oxide, aluminum oxide, silicon oxide (SiOₓ), titanium oxide, germanium oxide, yttrium oxide, zirconium oxide, and hafnium oxide; metal nitrides such as silicon nitride (SiNₓ); metal nitride oxides (metal oxide nitrides) such as nitride oxide silicon (SiOₓN_{y}); metal fluorides such as lithium fluoride, magnesium fluoride, aluminum fluoride, and calcium fluoride; and diamond-like carbon (DLC). Regarding the organic materials, examples include polymers such as polyethylene, polypropylene, polyvinylidene fluoride, poly-p-xylylene, and polyvinyl alcohol. Among them, an oxide, nitride, or nitride oxide of a metal, or DLC is preferable, and an oxide, nitride, or nitride oxide of silicon or aluminum is particularly preferable. The passivation layer may be a single layer or may have a multilayer constitution.

The method of forming the passivation layer is not particularly limited and, for example, PVD methods such as a vacuum deposition method, a sputtering method, an MBE (molecular beam epitaxy) method, a cluster ion beam method, an ion plating method, and a plasma polymerization method; various CVD methods including an atomic layer deposition method (an ALD method or an ALE method); a coating method; a printing method; and a transfer method can be applied. In the present invention, the passivation layer may also be used as a conductive layer.

<Gas Barrier Layer>

In particular, the passivation layer for the purpose of preventing penetration of active factors such as water molecules and oxygen molecules is also called a gas barrier layer, and it is preferable that the solar cell 10 according to the invention, especially, the organic thin-film solar cell has a gas barrier layer. The gas barrier layer is not particularly limited as far as the layer is a layer that prevents active factors such as water molecules and oxygen molecules, and the materials exemplified above as the passivation layer are generally used. These materials may be a pure substance, or may be a mixture including plural compositions or a graded composition. Among them, an oxide, nitride, or nitride oxide of silicon or aluminum is preferable.

The gas barrier layer may be a single layer or plural layers. The gas barrier layer may be a lamination layer of an organic material layer and an inorganic material layer, or may be an alternating lamination layer of plural organic material layers and plural inorganic material layers. The organic material layer is not particularly limited as far as the layer exhibits smoothness, but preferable examples include a layer formed from a polymer of (meth)acrylate. For the inorganic material layer, the above-described passivation layer material is preferable, and an oxide, nitride, or nitride oxide of silicon or aluminum is particularly preferable.

There is no particular limitation concerning the thickness of the inorganic material layer, but the thickness is, per one layer, generally from 5 nm to 500 nm, and preferably from 10 nm to 200 nm. The inorganic material layer may have a laminate structure including plural sub-layers. In this case, each sub-layer may have the same composition or a different composition. Further, as disclosed in U.S. Patent Application Publication No. 2004/0046497, the interface of the organic material layer formed from a polymer may be not clear, and a layer in which the composition thereof changes continuously in a film thickness direction may be possible.

The thickness of the solar cell 10 according to the invention is not particularly limited, but in the case of preparing an organic thin-film solar cell having optical transparency, the thickness thereof is preferably from 50 μm to 1 mm, and more preferably from 100 μm to 500 μm.

In the case of preparing a photovoltaic power generation module by using the solar cell 10 according to the invention, the description in “TAIYOKO HATSUDEN (Photovoltaic Power Generation)—Latest Technology and Systems—”, written by Yoshihiro Hamakawa, CMC Publishing Co., Ltd. (2000) and the like can be taken into consideration.

### EXAMPLES

Herein below, the present invention is more specifically described with reference to examples. The material, the amount of use, the ratios, the processing details, the processing order, and the like described in the following examples can be appropriately changed provided that the gist of the invention is not deviated from. Accordingly, the scope of the invention is not limited to the specific examples described below.

### Example 1

[Formation of Additional Electrode for Positive Electrode]

[Preparation of Silver Halide Emulsion]

In a reaction vessel, the following solution A was maintained at 34° C., and was adjusted to a pH of 2.95 using nitric acid (concentration: 6%), while being agitated at high speed using a mixing-agitation device described in JP-A No. 62-160128. Subsequently, the following solution B and the following solution C were added thereto at a constant flow rate over 8 minutes 6 seconds using a double-jet method. After the addition was completed, the pH of the resulting mixture was adjusted to 5.90 using sodium carbonate (concentration: 5%) and then, the following solution D and solution E were added thereto.

(Solution A)

| | |
|---|---|
| Alkali-processed inert gelatin (average | 18.7 g |
| molecular weight: 100,000) | |
| Sodium chloride | 0.31 g |
| Solution I (described below) | 1.59 cm³ |
| Pure water | 1,246 cm³ |

(Solution B)

| | |
|---|---|
| Silver nitrate | 169.9 g |
| Nitric acid (concentration: 6%) | 5.89 cm³ |

Pure water was added to give a total amount of 317.1 cm³.

(Solution C)

| | |
|---|---|
| Alkali-processed inert gelatin (average | 5.66 g |
| molecular weight: 100,000) | |
| Sodium chloride | 58.8 g |
| Potassium bromide | 13.3 g |
| Solution I (described below) | 0.85 cm³ |
| Solution II (described below) | 2.72 cm³ |

Pure water was added to give a total amount of 317.1 cm³.

(Solution D)

| | |
|---|---|
| 2-Methyl-4hydroxy-1,3,3a,7-tetrazaindene | 0.56 g |
| Pure water | 112.1 cm³ |

(Solution E)

| | |
|---|---|
| Alkali-processed inert gelatin (average | 3.96 g |
| molecular weight: 100,000) | |
| Solution I (described below) | 0.40 cm³ |
| Pure water | 128.5 cm³ |

<Solution I>

10% by mass methanol solution of polyisopropylene-polyethylene-oxy disuccinic acid ester sodium salt

<Solution II>

10% by mass aqueous solution of rhodium hexachloride complex

After the above operations were completed, the reaction mixture was subjected to desalting and washing treatment at 40° C. using a flocculation method carried out conventionally and then, solution F and an antiseptic were added thereto and thoroughly dispersed at 60° C., followed by adjusting the pH to 5.90 at 40° C., and finally, a silver chlorobromide cubic particle emulsion containing 10 mol % of silver bromide and having an average particle diameter of 0.09 μm and a coefficient of variation of 10% was obtained.

(Solution F)

| | |
|---|---|
| Alkali-processed inert gelatin (average | 16.5 g |
| molecular weight: 100,000) | |
| Pure water | 139.8 cm³ |

Chemical sensitization was conducted at 40° C. for 80 minutes with respect to the silver chlorobromide cubic particle emulsion using sodium thiosulfate in an amount of 20 mg per 1 mol of silver halide, and after the chemical sensitization was completed, 4-hydroxy-6-methyl-1,3,3a,7-tetrazaindene (TAT) in an amount of 500 mg per 1 mol of silver halide and 1-phenyl-5-mercaptotetrazole in an amount of 150 mg per 1 mol of silver halide were added thereto to obtain a silver halide emulsion. The volume ratio of silver halide particles to gelatin (silver halide particles/gelatin) in the silver halide emulsion was 0.625.

[Coating]

Further, as a hardener, tetrakis(vinylsulfonylmethyl)methane was added such that the ratio was 200 mg of tetrakis(vinylsulfonylmethyl)methane per 1 g of gelatin, and as a coating aid (a surfactant), sodium di(2-ethylhexyl)sulfosuccinate was added thereto, whereby the surface tension was adjusted.

The thus obtained coating liquid was applied onto one side (the other side had been subjected to anti-reflection processing) of a polyethylene naphthalate (PEN) film substrate (support), which had a thickness of 100 μm and a transparency of 92% and was provided with an undercoat layer, such that the coating weight based on silver was 0.625 g·m⁻², and thereafter, a curing treatment was performed at 50° C. for 24 hours, whereby a photosensitive material was obtained.

[Exposure]

The obtained photosensitive material was exposed to light through a photomask with a mesh pattern (having a line width of 5 μm and a pitch of 300 μm), using ultraviolet ray exposing equipment.

[Chemical Development]

The photosensitive material that was exposed to light was subjected to a development treatment at 25° C. for 60 seconds using the following developing solution (DEV-1), and thereafter, a fixing treatment was conducted at 25° C. for 120 seconds using the following fixing solution (FIX-1).

(DEV-1)

| | |
|---|---|
| Pure water | 500 cm³ |
| Metol | 2 g |
| Sodium sulfite anhydride | 80 g |
| Hydroquinone | 4 g |
| Borax | 4 g |
| Sodium thiosulfate | 10 g |
| Potassium bromide | 0.5 g |

Water was added to give a total amount of 1000 cm³.

(FIX-1)

| | |
|---|---|
| Pure water | 750 cm³ |
| Sodium thiosulfate | 250 g |
| Sodium sulfite anhydride | 15 g |
| Glacial acetic acid | 15 cm³ |
| Potassium alum | 15 g |

Water was added to give a total amount of 1000 cm³.

[Physical Development]

Next, using the following physical developing solution (PDEV-1), physical development was conducted at 30° C. for 10 minutes and then, a washing treatment was conducted by rinsing for 10 minutes using tap water.

(PDEV-1)

| | |
|---|---|
| Pure water | 900 cm³ |
| Citric acid | 10 g |
| Trisodium citrate | 1 g |
| Aqueous ammonia (28%) | 1.5 g |
| Hydroquinone | 2.3 g |
| Silver nitrate | 0.23 g |

Water was added to give a total amount of 1000 cm³.

[Electrolytic Plating]

After performing the physical development, a copper electrolytic plating treatment was conducted at 25° C. using the following electrolytic plating liquid, and then a washing and drying treatment was conducted. The adjustment of electric current in the copper electrolytic plating was carried out to provide 3 A for 1 minute, then 1 A for 12 minutes, for a total of 13 minutes. After the plating treatment was completed, a washing treatment was conducted by rinsing for 10 minutes using tap water, and drying was conducted using dry air (50° C.) until a dry state was reached.

(Electrolytic Plating Liquid)

| | |
|---|---|
| Copper sulfate (pentahydrate) | 200 g |
| Sulfuric acid | 50 g |
| Sodium chloride | 0.1 g |

Water was added to give a total amount of 1000 cm³.

The above photosensitive material that was subjected to the chemical developing, physical developing, and electrolytic plating treatments was observed using an electron microscope, and it was confirmed that a mesh-patterned silver with a line width of 19 μm and a pitch of 300 μm was formed on the PEN film substrate (support).

[Formation of Positive Electrode]

As for the low-resistivity layer (first conductive layer) that forms the positive electrode, 5% by mass of dimethylsulfoxide was added to an aqueous solution of PEDOT-PSS (CLEVIOS PH 500, manufactured by H.C. Starck Clevios GmbH), and the resulting solution was applied to the mesh-patterned silver, followed by performing a heat treatment at 120° C. for 20 minutes. In this manner, a low-resistivity layer was formed, which had a film thickness of 0.2 μm and a volume resistivity of 1 mΩ·cm.

Next, as the high-resistivity layer (second conductive layer), an aqueous solution of PEDOT-PSS having a different composition (CLEVIOS P VP. AI4083, manufactured by H.C. Starck Clevios GmbH) was applied to the low-resistivity layer, followed by performing a heat treatment at 120° C. for 20 minutes. In this manner, a high-resistivity layer was formed, which had a film thickness of 0.04 μm and a volume resistivity of 1 kΩ·cm.

[Formation of Photoelectric Conversion Layer]

A composition obtained by dissolving 20 mg of P3HT (LISICON SP001, manufactured by Merck & Co., Inc.) as an electron-donating material and 14 mg of PCBM (NANOM SPECTRA E100H, manufactured by Frontier Carbon Corp.) as an electron-accepting material in 1 cm³ of chlorobenzene was applied to the high-resistivity layer under dry nitrogen atmosphere, followed by performing a heat treatment at 130° C. for 20 minutes. In this manner, a bulk heterojunction type photoelectric conversion layer was formed, which had a film thickness of 0.1 μm.

[Formation of Electron Transport Layer]

An ethanol solution including 1% by weight of titanium(IV) isopropoxide was applied to the photoelectric conversion layer, and was dried in air. In this manner, an electron transport layer was formed, which had a film thickness of 0.01 μm.

[Formation of Translucent Metal Negative Electrode and Additional Metal Electrode for Negative Electrode]

As the translucent metal negative electrode, gold (film thickness: 10 nm) was vacuum-deposited. In this process, a shadow mask was used so that the element area became 1 cm².

Subsequently, as the additional metal electrode for the negative electrode, aluminum (film thickness: 0.4 μm) was vacuum-deposited. In this process, two-stage deposition was conducted using a banded shadow mask having an aperture width of 0.1 mm and a 2 mm pitch, whereby a square grid-like additional metal electrode for the negative electrode was prepared.

The thus obtained organic thin-film solar cell in the state of being not sealed was irradiated with a solar simulator of 80 mW·cm⁻², and the conversion efficiency was measured. Specifically, while irradiating the organic thin-film solar cell with a light source prepared using a xenon lamp (96000, manufactured by Newport Corporation) and an air mass filter (84094, manufactured by Newport Corporation) in combination, a voltage of from −0.2 V to 0.8 V was applied using a source meter (MODEL 2400, manufactured by Keithley Instruments), and the current value was measured. From the obtained current-voltage characteristics, conversion efficiency was determined using PECCELL I-V CURVE ANALYZER (VER. 2.1, produced by Peccell Technologies Inc.). The measurement results are shown in Table 1.

### Examples 2 to 9 and Comparative Examples 1 to 6

Organic thin-film solar cells were prepared in a manner similar to that in Example 1, except that the metal negative electrode and the additional metal electrode for the negative electrode were changed as shown in Table 1, and the conversion efficiency thereof was measured.

### Example 10

[Formation of Additional Electrode for Positive Electrode/Positive Electrode]

The additional electrode for the positive electrode and the positive electrode were formed in a manner similar to that in Example 1.

[Formation of Photoelectric Conversion Layer]

A composition obtained by dissolving P3HT and PCBM in chlorobenzene was applied to the positive electrode in a manner similar to that in Example 1, and without performing a heat treatment, a bulk heterojunction type photoelectric conversion layer was formed.

[Formation of Electron Transport Layer/Additional Metal Electrode for Negative Electrode/Translucent Metal Negative Electrode]

As the electron transport layer, aluminum (film thickness: 2 nm) was vacuum-deposited on the whole surface of the photoelectric conversion layer.

Subsequently, as the additional metal electrode for the negative electrode, aluminum (film thickness: 0.4 μm) was vacuum-deposited on the electron transport layer. In this process, two-stage deposition was conducted using a banded shadow mask having an aperture width of 0.1 mm and a 2 mm pitch, whereby a square grid-like additional metal electrode for the negative electrode was prepared.

Further, as the translucent negative electrode, silver (film thickness: 10 nm) was vacuum-deposited. In this process, a shadow mask was used so that the element area became 1 cm². Finally, a heat treatment was conducted at 130° C. for 20 min to oxidize the aluminum of the electron transport layer.

In this manner, an organic thin-film solar cell was prepared, and the conversion efficiency thereof was measured.

### Examples 11 to 13

Organic thin-film solar cells were prepared in a manner similar to that in Example 10, except that the electron transport layer, the metal negative electrode, and the additional metal electrode for the negative electrode were changed as shown in Table 1, and the conversion efficiency thereof was measured.

Further, with regard to each of the organic thin-film solar cells of the Examples and the Comparative Examples, the conversion efficiency 10 days after the preparation was measured, and a relative value was determined with the initial value being designated as 1.

TABLE 1

| | | Additional metal | Conversion | |
|---|---|---|---|---|
| Electron | | electrode for | Efficiency | |
| Transport | Translucent Metal | Negative | After 10 Days | |
| layer | Negative Electrode | Electrode | (relative value) | |
| Titanium | Gold: 10 nm | Aluminum: | 1.0 | Example 1 |
| oxide: 10 nm | | 0.4 μm | | |
| | | Silver: 0.4 μm | 1.0 | Example 2 |
| | Silver: 15 nm | Aluminum: | 0.98 | Example 3 |
| | | 0.4 μm | | |
| | | Zinc: 0.4 μm | 0.97 | Example 4 |
| | | Nickel: 0.4 μm | 0.94 | Example 5 |
| | | Copper: 0.4 μm | 0.92 | Example 6 |
| | | Silver: 0.4 μm | 0.78 | Comparative |
| | | | | Example 1 |
| | | Gold: 0.4 μm | 0.42 | Comparative |
| | | | | Example 2 |
| | Copper: 15 nm | Aluminum: | 0.93 | Example 7 |
| | | 0.4 μm | | |
| | | Zinc: 0.4 μm | 0.92 | Example 8 |
| | | Nickel: 0.4 μm | 0.90 | Example 9 |
| | | Copper: 0.4 μm | 0.67 | Comparative |
| | | | | Example 3 |
| | | Silver: 0.4 μm | 0.34 | Comparative |
| | | | | Example 4 |
| | | Gold: 0.4 μm | 0.31 | Comparative |
| | | | | Example 5 |
| | Aluminum: | Aluminum: | 0.22 | Comparative |
| | 15 nm | 0.4 μm | | Example 6 |
| Aluminum | Silver: 10 nm | | 0.85 | Example 10 |
| (oxide): 2 nm | Silver: 15 nm | | 0.88 | Example 11 |
| | Silver: 20 nm | | 0.91 | Example 12 |
| Zinc (oxide): | Silver: 15 nm | Zinc: 0.4 μm | 0.86 | Example 13 |
| 2 nm | | | | |

As shown in Table 1, in the Examples, the conversion efficiencies after 10 days maintained higher values compared to the Comparative Examples.

1. A solar cell comprising:
a support;
a positive electrode disposed on the support;
a photoelectric conversion layer disposed on the positive electrode;
a translucent metal negative electrode which is disposed on the photoelectric conversion layer and is provided with a positive standard electrode potential; and
an additional metal electrode for the negative electrode, the additional metal electrode being disposed so as to be in contact with the metal negative electrode and being provided with a standard electrode potential that is less than the standard electrode potential of the metal negative electrode.

2. The solar cell according to claim 1, wherein the metal negative electrode comprises at least one selected from the group consisting of copper, silver and gold, and the additional metal electrode for the negative electrode comprises at least one selected from the group consisting of aluminum, nickel, copper and zinc.

3. The solar cell according to claim 1, wherein the photoelectric conversion layer includes an electron-donating region formed from an organic material.

4. The solar cell according to claim 1, wherein the photoelectric conversion layer has a bulk-heterojunction.

5. The solar cell according to claim 1, wherein an electron transport layer is disposed between the photoelectric conversion layer and the metal negative electrode.

6. The solar cell according to claim 5, wherein the electron transport layer comprises a metal that forms the additional metal electrode for the negative electrode.

7. The solar cell according to claim 1, wherein the positive electrode comprises a first conductive layer disposed on a side of the support and a second conductive layer that is closer to the photoelectric conversion layer than the first conductive layer and has a higher volume resistivity than that of the first conductive layer.

8. The solar cell according to claim 1, further comprising an additional electrode for the positive electrode, the additional electrode being disposed so as to be in contact with the positive electrode.

9. The solar cell according to claim 8, wherein the additional electrode for the positive electrode comprises silver and a hydrophilic polymer.

10. The solar cell according to claim 1, wherein the additional metal electrode for the negative electrode is disposed on the metal negative electrode.

11. The solar cell according to claim 1, wherein at least a portion of the metal negative electrode is disposed on the additional metal electrode for the negative electrode.
